(19) United States
(12) Patent Application Publication
(10) Pub. No.: US 2006/0063028 A1
(43) Pub. Date: Mar. 23, 2006

(54) Two sided light emitting device

(76) Inventor: Jeroom Frans Marie Leurs, Heerlen (NL)

Correspondence Address: PHILIPS INTELLECTUAL PROPERTY & STANDARDS, P.O. BOX 3001, BRIARCLIFF MANOR, NY, 10510, US

(21) Appl. No.: 10/552,077

(22) PCT Filed: Apr. 6, 2004
(86) PCT No.: PCT/IB04/50402

§ 371 Date: Oct. 4, 2005

(30) Foreign Application Priority Data
Apr. 8, 2003 (EP) 03100938.4

(51) Int. Cl. B32B 19/00

(52) U.S. Cl. 428/690; 313/501; 428/917; 428/68; 313/504

(57) ABSTRACT

A two-sided light emitting device has, spaced and parallel to one another, a first and a second substrate. The facing sides of the substrates are each provided with a light emitting device, such as a display or a lighting device, which device has a light emitting surface facing the substrate onto which it is provided. The substrates are fastened to one another by means of, for example, a perimeter seal providing a closed housing for the first and second light emitting devices. The substrates protect the first and second light emitting devices against ingress of dust, moisture and the like. The second substrate assists in protecting the first light emitting device and the first substrate assists in protecting the second light emitting device thus providing a well-protected and thin two-sided light emitting device.

A two-sided light emitting device is a device, a lighting or a display device, having at least two light emitting surfaces, a first light emitting surface for light emission to a first side and a second light emitting surface for light emission to a second side. Such two-sided light emitting devices are known as such and are used in for example mobile phones. For example, JP2000-058260 display a two-sided organic electroluminescent device wherein a metal cathode is provided on each side with organic electroluminescent material and a transparent ITO anode. This device has a disadvantage in that its manufacture is not compatible with conventional methods of manufacturing organic electroluminescent devices. Conventionally, organic electroluminescent devices are manufactured by successive deposition of layers. Because of its reactivity the metal cathode is conventionally formed at a final stage of manufacture. If the device of JP2000-058260 is manufactured in a conventionally manner the metal cathode layer cannot be deposited at a final stage. Also, having a central cathode layer the displays formed on either side have the same size. For many applications this is unnecessary or even undesirable.

It is an object of the invention, inter alia, to provide a two-sided light emitting device which does not have the above-mentioned disadvantage and is capable of being manufactured using conventional manufacturing methods. Moreover, the two-sided light emitting device should be thin and well-protected from outside influences such as dust, moisture and the like.

These and other objects are achieved by means of a two-sided light emitting device comprising a first light emitting device having a first light emitting surface, a second light emitting device having a second light emitting surface, a first substrate light-transmissive for light emitted by the first light emitting device, a second substrate light-transmissive for light emitted by the second light emitting device and fastening means fastening the first substrate to the second substrate wherein the first and second substrate are arranged parallel and spaced to one another, the first light emitting deviceis, with the first light emitting surface facing the first substrate, provided on a side of the first substrate facing the second substrate providing the two-sided light emitting device with a first light emission side and the second light emitting device is, with the second light emitting surface facing the second substrate, provided on a side of the second substrate facing the first substrate providing the two-sided fight emitting device with a second light emission side opposite the first.

The two-sided light emitting device in accordance with the invention has two separate light emitting devices, a first and a second, which each may be manufactured in a conventional manner. Moreover, having two such separate light emitting devices, operation of each device may proceed independent of the other and use of different devices, in size and/or type is easily accomplished. Since the first and second light emitting device are spatially separated from one another, risk of cross-talk is reduced if not eliminated. By providing the first and second light emitting device on facing sides of individual first substrates a thin, compact and robust arrangement is obtained. The first substrate serves to protect the second light emitting device whereas the second substrate serves to protect the first light emitting device. No separate protective plates are necessary.

In a preferred embodiment of the two-sided light emitting device in accordance with the invention the first and/or second light emitting device is an organic, low molecular or polymer, electroluminescent device.

Providing the facing sides of the first and/or the second substrates with electroluminescent devices is of particular advantage if organic or more particular polymer electroluminescent devices are used. In order to operate properly, such devices need protection from moisture and/or oxygen. To provide such protection, an organic electroluminescent device is commonly enclosed in an air and moisture proof housing. Such a housing is typically formed of a substrate, onto the device is provided, and a cover which, by means of a perimeter seal, is attached to the substrate. In the two-sided light emitting device in accordance with the invention, the first substrate serves as cover for the second and vice versa. Thus only a single perimeter seal is required to enclose two light emitting devices which results in a thin construction because the seal line adds substantially to the overall thickness. Being more thin also allows a more flexible two-side light emitting device to be made if desired.

In a particular embodiment of the two-side light emitting device in accordance with the invention, the fastening means is a perimeter seal providing, in co-operation with the first and second substrate, a closed housing for the first and second light emitting device.

The first and second substrate may be fastened using any suitable fastening means such as clamps, rivets, tape bolts or adhesive such as glue. A preferred fastening means is a perimeter seal which connects the first and second substrate and completely surrounds both the first and second light emitting device. The perimeter seal provides a closed housing preventing ingress of unwanted contaminants such as dust, moisture and/or oxygen.

Preferably the perimeter seal is formed of organic adhesive material such as epoxy adhesive. Alternatively, a gasket may be used which by means of glue or other means is secured, air and/or moisture proof, to the first and second substrate. If the two-sided light emitting device comprises one or more organic electroluminescent devices a getter may be used which getters any oxygen and/or moisture that may enter the housing via the perimeter seal.

The substrate, first and second, may be formed of any (composite) material, glass and synthetic resin being preferred materials, provided the part facing the light emitting device is light transmissive for the light emitted by the said light emitting device. If the light emitting device is air and/or moisture-sensitive the synthetic resin is preferably combined with one or more barrier layers impervious to moisture and/or oxygen. Such substrates are known as such.

In a preferred embodiment of the two-sided light emitting device in accordance with the invention the first and/or second substrate is an integral part of the first and/or the second light emitting device respectively.

Most light emitting devices, lighting and display devices alike, liquid crystal display and organic electroluminescent displays being examples, include one or more substrates as an integral part of the device. A particular compact arrangement is obtained if such a substrate is used as the first or the second substrate.

At least the first or second light emitting device may be a display device. In principle any display device more particular thin-film display device may be used but preferably the display is an organic electroluminescent display. Alternatively, at least the first or second light emitting device may be a lighting device.

Having two separate light emitting devices allows the possibility of using two different light emitting devices. In a particular embodiment of the two-sided display in accordance with the invention, the first light emitting device is a stand-by display and the second light emitting device is a display-on-demand display. The stand-by display which is on most of the time may be a display of low resolution and low power whereas the display-on-demand may be high resolution and high power, the combination providing a good balance with the quality of display and power consumption.

The invention may be used for any application in which displays or lighting devices are used. A preferred lighting device is a flat lighting device of large surface area such as a lighting tile or sheet. A preferred display application is a mobile phone or any other device including mobile phone functionality.

These and other aspects of the invention will be apparent from and elucidated with reference to the drawings and the embodiments described hereinafter.

In the drawings:

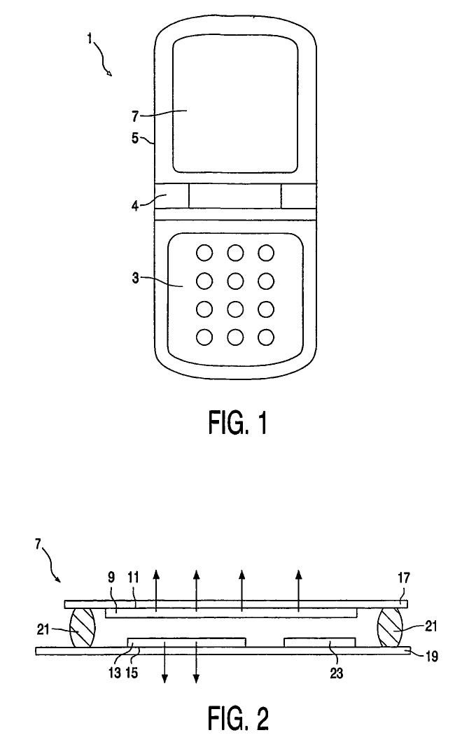

FIG. 1 shows, schematically, in a plan view, a mobile phone comprising a two-sided light emitting device; and

FIG. 2 shows, schematically, in a cross-sectional view, a two-sided light emitting device in accordance with the invention in the form of a display.

FIG. 1 shows, schematically, in a plan view, a mobile phone 1. The phone 1 has a keypad member 3 and a display member 5 connected via a hinge 4 to the keypad member 3. The display member 5 has a two-sided light emitting device in the form of a display 7 providing a viewing side to both sides of the display member 5, one primarily for use when the phone is open, the other to be used when the phone is closed.

FIG. 2 shows, schematically, in a cross-sectional view, a two-sided light emitting device in accordance with the invention in the form of a display.

The two-sided display 7 comprises a first light emitting device, here display 9, having a first electroluminescent (display) surface 11 and a second light emitting device, here display 13, having a second electroluminescent (display) surface 15.

The first and/or second display may be of any type, such as a liquid crystal display, in particular a single-substrate LCD, an electro-phoretic display, an electro-wetting display, an electroluminescent display or even a plasma display. Preferably, the display 9 and/or 13 is an organic, low molecular or polymeric, electroluminescent display. Such displays are thin and can be manufactured using a single substrate. Moreover, since organic electroluminescent displays are particularly sensitive to oxygen and moisture the protection offered by the substrates 17 and 19 is of particular advantage. The first display 9 and similarly the second display 13 may be a single pixel display merely providing an indicator or signage function or a multi-pixel display capable of displaying images such as text, graphics and video. The image on display may be a fixed image or a variable image on input of image data provided by driving circuitry (not shown). The first or second display may be a segmented, optionally time-multiplexed, or a matrix, active or passive, display. The first and second displays 9 and 13 may be monochrome, multi-color or full-color displays. The driving circuitry may be hard-wired to provide the same image information to each display or the driving circuitry may be wired to allow different images to be displayed on the first and second display at any time. The first and second display may be of a same or different type, size and/or display technology. For many applications, such a mobile phone, it may suffice to combine a simple inexpensive low-resolution display with a more complex, expensive high-resolution display. For example, an indicator or fixed image display which is continuously driven in stand-by mode may be combined with a (full-color) matrix display which displays only on demand. Not necessarily, but typically, the first and second displays of the two-sided display 7 are themselves one-sided displays. In FIG. 2 the first display is one-sided display having a display surface 11 and the second display 13 is a one-sided display having display surface 15. Each display surface may have any shape, mutually the same or different.

The two-sided display has a first substrate 17 onto which the first display 9 is provided. The first substrate 17 serves to support, position and protect the displays from external influences such as mechanical forces exerted on the display, dust, and other contaminants such as air and moisture and furthermore provides mechanical integrity to the two-sided display. In order to allow light emitted by the first display 9 to leave the two-sided display 7 at least (a part of) the region of the first substrate 17 opposite the display surface 11 is to be light transmissive for such emitted light The second substrate 19 provides functionality similar to that provided by the first substrate 17 to that by the second display 13. Only the region opposite the display surface 11, 15 respectively may have such light transmission properties or the entire substrate may have such properties.

The first and second substrate may be identical or different. Materials which may be used to form the first and second substrates include metal, ceramics, textile wood, and glass. Synthetic resin may also be used. Glass and synthetic resin are preferred. In particular if the two-sided display comprises organic electroluminescent displays moisture and/or air proof substrates are required. Substrates including metal or glass sheets are useful in this respect. In case of a synthetic resin based substrate, one or more barrier layer impervious to air and/or oxygen need to be included to effectively protect the light emitting devices. Such substrates are known in the art as such.

The substrates 17 and 19 typically have a thickness in a range from about 50 μm to about 2 cm, more particular 100 to about 1 mm. The substrates may be flexible or rigid.

The substrates 17 and 19 are arranged parallel and spaced to one another. In order to fasten the substrate 17 and 19 to one another fastening means 21 are employed. In principle any fastening means may be used. For example a clamps, rivets or nut and bolt means may be used. The substrates may also be glued together. To keep the first and second substrate at a fixed separation, spacers may be used such as spheres or rods having a desired diameter. A gasket which runs around the first and second display may also be used, such an arrangement also referred to as a perimeter seal. In co-operation with the first and second substrate the gasket provides a closed housing for the first and second display and hence an enhanced protection against the ingress of dust, moisture and air. If the gasket is formed of resilient material mechanical shock protection is also improved. Adhesive layers provided between the gasket and the substrates may be used to further seal the two-sided display. As an alternative to a gasket an adhesive perimeter seal may be used such as a seal of epoxy adhesive such seals being known in the art for sealing housings for light emitting devices.

If the closed housing as such provides insufficient protection against ingress of water and/or air to the extent that such ingress degrades the first and/or second display such as would be the case if an adhesive epoxy perimeter seal is used to seal a housing for an organic light emitting device, a getter 23 adapted to getter such moisture and/or air (oxygen) may be used. Suitable getter for this purpose is BaO.

In addition or alternatively the displays 9 and 13 may themselves be encapsulated by means of a a barrier layer impervious to air and/or moisture.

The first light emitting device 9 is provided on a side of the first substrate 17 facing the second substrate 19 such that the first display surface 11 faces the first substrate 17. Similarly, the second display 13 is provided on a side of the second substrate 19 facing the first substrate 17 such that the second display surface 15 faces the second substrate 19. In operation, the first light emitting device 9 provides a first light emission side and the second light emitting device 13 a second light emission side opposite the first.

The displays being arranged on facing sides of the first and second substrates results in a two-sided display which is particularly thin and robust because the first substrate is part of the housing for the second display and vice versa Only a single perimeter seal is required. Such shared use of substrates results in a thinner display.

Displays which can be suitably used in the two-sided display in accordance with the invention typically comprise one or more substrates. For example, an organic electroluminescent display typically comprises one substrate onto which a first electrode layer, an electroluminescent layer and a second electrode layer is provided. A conventional LCD typically has two substrates. Such display may simply be provided on the first or second substrate of the two-sided display. However, further integration and thus thinner two-sided displays are obtained if the substrate 17 and/or 19 is an integral part of the display 9 and/or 13 respectively.

Display and lighting devices being particular examples of light emitting devices, in the text accompanying FIG. 2, the term “display” may be replaced by “lighting device”.

1. A two-sided light emitting device comprising a first light emitting device having a first light emitting surface, a second light emitting device having a second light emitting surface, a first substrate light-transmissive for light emitted by the first light emitting device, a second substrate light-transmissive for light emitted by the second light emitting device and fastening means fastening the first substrate to the second substrate wherein the first and second substrate are arranged parallel and spaced to one another, the first light emitting device is, with the first light emitting surface facing the first substrate, provided on a side of the first substrate facing the second substrate providing the two-sided light emitting device with a first light emission side and the second light emitting device is, with the second light emitting surface facing the second substrate, provided on a side of the second substrate facing the first substrate providing the two-sided light emitting device with a second light emission side opposite the first.

2. A two-sided light emitting device as claimed in claim 1 wherein at least the first or second light emitting device is an organic, low molecular or polymer, electroluminescent device.

3. A two-sided light emitting device as claimed in claim 1 wherein the fastening means is a perimeter seal providing, in co-operation with the first and second substrate, a closed housing for the first and second light emitting device.

4. A two-sided light emitting device as claimed in claim 3 wherein the perimeter seal is formed of organic adhesive material and, optionally, comprises a getter for gettering oxygen and/or water arranged within the closed housing.

5. A two-sided light emitting device as claimed in claim 1, wherein the first and/or second substrate comprises a sheet of glass or, in combination with one or more barrier layers impervious to water and/or oxygen, synthetic resin.

6. A two-sided light emitting device as claimed in claim 1, wherein the first and/or second substrate is an integral part of the first and/or the second light emitting device respectively.

7. A two-sided light emitting device as claimed in claim 1, wherein at least the first or the second light emitting device is a display device.

8. A two-sided light emitting device as claimed in claim 7, wherein the first light emitting device is a stand-by display and the second light emitting device is a display-on-demand display.

9. A mobile phone having a two-sided light emitting device as claimed in claim 1.

10. A two-sided light emitting device as claimed in claim 1, wherein at least the first or the second light emitting device is a lighting device.
